(19) United States
(12) Patent Application Publication
(10) Pub. No.: US 2004/0263438 A1
(43) Pub. Date: Dec. 30, 2004

(54) Display

(75) Inventors: Kenya Uesugi, Ogaki-shi (JP); Michiru Senda, Gifu-shi (JP)

Correspondence Address: McDERMOTT, WILL & EMERY, 600 13th Street, N.W., Washington, DC, 20005-3096, US

(73) Assignee: SANYO ELECTRIC CO., LTD.

(21) Appl. No.: 10/811,829

(22) Filed: Mar. 30, 2004

(30) Foreign Application Priority Data
Jun. 27, 2003 (JP) JP2003-185542

(51) Int. Cl. G09G 3/30

(52) U.S. Cl. 345/76

(57) ABSTRACT

There is provided a display which can prevent image deterioration. The display is provide with a shift register circuit including a first circuit part comprising a first transistor of first conductivity type connected to a first potential side and turned on in response to a clock signal, a second transistor of first conductivity type connected to a second potential side, a third transistor of first conductivity type connected between a gate of the first transistor and the second potential and a high resistance connected between the gate of the first transistor and a clock signal line.

### BACKGROUND OF THE INVENTION

1. Field of the Invention

The present invention relates to a display and more particularly, it relates to a display provided with a shift register circuit.

2. Description of the Background Art

Conventionally, a resistance loading type of inverter circuit has been well known. This is disclosed in p.184-187 in “Basis of Semiconductor Device” written by Seigo Kishino, published by Ohmsha, Ltd., Apr. 25 in 1985, for example. In addition, conventionally, a shift register circuit comprising the above-described resistance loading type of inverter circuit has been known. The shift register circuit is used as a circuit for driving a drain line of a liquid crystal display or an organic EL display, for example.

FIG. 13 is a circuit diagram showing a shift register circuit comprising the conventional resistance loading type of inerter circuit. Referring to FIG. 13, a conventional shift register circuit 100a consists of an input-side circuit part 101a and an output-side circuit part 102a. A second stage of shift register circuit 100b consists of an input-side circuit part 101b and an output-side circuit part 102b.

The input-side circuit part 101a constituting the first stage of shift register circuit 100a comprises n-channel transistors NT101 and NT102, a capacitor C101, and a resistance R101. Hereinafter, the n-channel transistors NT101 and NT102 are referred to as the transistors NT101 and NT102, respectively in the description of the prior art. A source of the transistor NT101 is connected to a node ND101 and a start signal ST is input to a drain thereof. A clock signal CLK1 is supplied to a gate of the transistor NT101. One electrode of a capacitor C101 is connected to the node ND101 and the other electrode is connected to a negative-side potential VSS. In addition, a source of the transistor NT102 is connected to the negative-side potential VSS and a drain thereof is connected to a node ND102. One terminal of a resistance R101 is connected to the node ND102 and the other terminal is connected to the positive-side potential VDD. Thus, the transistor NT102 and the resistance R101 constitute an inverter circuit.

In addition, an output-side circuit part 102a constituting the first stage of shift register circuit 100a comprises an n-channel transistor NT103 and a resistance R102. Hereinafter, the n-channel transistor NT103 is referred to as a transistor NT103 in the description of the prior art. A source of the transistor NT103 is connected to the negative-side potential VSS and a drain thereof is connected to a node ND103. One terminal of the resistance R102 is connected to the node ND103 and the other terminal is connected to the positive-side potential VDD. Thus, the transistor NT103 and the resistance R102 constitutes an inverter circuit.

In addition, the second or later stage of shift register circuit also has the same circuit constitution as that of the above-described first stage of shift register circuit 100a. In addition, it is constituted such that the input-side circuit part of the later stage of shift register circuit is connected to the output node of the former stage of output-side circuit part. In addition, the clock signal CLK1 is supplied to the gate of the transistor NT101 of the input-side circuit part arranged at the odd-numbered stage as described above, and a clock signal CLK2 is supplied to the gate of the transistor NT101 of the input-side circuit part arranged at the even-numbered stage.

FIG. 14 is a timing chart of the conventional shift register circuit shown in FIG. 13. A description is made of an operation of the conventional shift register circuit with reference to FIGS. 13 and 14.

First, a start signal ST becomes H level. Then, a clock signal CLK1 becomes H level. Thus, in the first stage of shift register circuit 100a, since the transistor NT101 is turned on and the potential of the node ND101 becomes H level, the transistor NT102 is turned on. Therefore, since the potential of the node ND102 is lowered to L level, the transistor NT103 is turned off. As a result, since the potential of the node ND103 is heightened to H level, the output signal SR1 at H level is output from the first stage of shift register circuit 100a. In addition, while the clock signal CLK1 is at H level, the potential at H level is charged to the capacitor C101.

Then, the clock signal CLK1 becomes L level. Thus, in the first stage of shift register circuit 100a, the transistor NT101 is turned off. Then, the start signal ST becomes L level. Here, even when the transistor NT101 is turned off, since the potential of the node ND101 is held at H level which is higher than the potential at H level stored in the capacitor C101, the transistor NT102 is held in on state. Therefore, since the potential of the node ND102 is not heightened to H level, the signal at L level is kept supplied to the gate of the transistor NT103. Thus, since the transistor NT103 is kept in off state, the output signal SR1 at H level is kept output from the first stage of shift register circuit 100a.

Then, the clock signal CLK2 becomes H level. Then, since the output signal SR1 at H level of the first stage of shift register circuit 100a is input to the second stage of shift register circuit 100b, the same operation as that of the first stage of shift register circuit 100a described above is performed. Therefore, the output signal SR2 at H level is output from the second stage of shift register circuit 100b.

Then, the clock signal CLK1 becomes H level again. Thus, in the first stage of shift register circuit 100a, the transistor NT101 is turned on. At this time, the potential of the node ND101 is lowered to L level because the start signal ST becomes L level. Thus, the transistor NT102 is turned off. Therefore, since the potential of the node ND102 is heightened to H level, the transistor NT103 is turned on. As a result, since the potential of the node ND103 is lowered from H level to L level, the output signal SR1 at L level is output from the first stage of shift register circuit 100a.

According to the above described operation, output signals (SR1, SR2, SR3 . . . ) at H level whose timings are shifted are sequentially output from respective stages of shift register circuits. Thus, predetermined picture signals can be sequentially supplied to the drain line, by connecting the drain line to the picture signal line through the horizontal switches which are turned on in response to the output signals (SR1, SR2, SR3 . . . ) at H level.

However, according to the conventional shift register circuit shown in FIG. 13, the moment the output signal (SR3, for example) output from the predetermined stage of shift register circuit is switched from L level to H level, and the moment the output signal (SR1, for example) output from the shift register circuit two stages prior to the predetermined stage overlap with each other in some cases. In this case, since the horizontal switch corresponding to the predetermined stage of shift register circuit is turned on at the moment the horizontal switch corresponding to the shift register circuit two stages prior to the predetermined stage is switched from on state to off state, a noise is generated in the signal supplied through the horizontal switch two stages prior to the predetermined stage. Thus, there is a problem such that the picture signal in which the noise is generated in the drain line is supplied when the drain line is connected to the picture signal line in the display through the horizontal switch which is turned on in response to the output signal at H level of the shift register circuit. As a result, when the above conventional shift register circuit is used in the circuit which drives the drain line of the display, the image of the display deteriorates because of the noise of the picture signal.

### SUMMARY OF THE INVENTION

The present invention was made to provide a display which can prevent image deterioration.

In order to solve the above problems, a display according to an aspect of the present invention is provided with a shift register circuit including a first circuit part comprising a first transistor of first conductivity type connected to a first potential side and turned on in response to a clock signal, a second transistor of first conductivity type connected to a second potential side, a third transistor of first conductivity type connected between a gate of the first transistor and the second potential, and a high resistance connected between the gate of the first transistor and a clock signal line supplying the clock signal.

According to the display of this aspect, since response speed when the first transistor is turned on is slowed, a signal output from the shift register circuit when the first transistor is in on state can be delayed. Therefore, when it is assumed that the first transistor of the shift register circuit two stages prior to the predetermined stage is turned off while the first transistor of the predetermined stage of shift register circuit is in on state, response speed of a horizontal switch corresponding to the predetermined stage of shift register circuit is slowed and response speed of a horizontal switch corresponding to the shift register circuit two stage prior to the predetermined stage is quickened. Thus, the moment the predetermined stage of horizontal switch is switched from off state to on state is prevented from overlapping with the moment the horizontal switch two states prior to the predetermined stage is switched on state to off state. Therefore, since the predetermined stage of horizontal switch can be turned on after the horizontal switch two stages prior to the predetermined stage was turned off, the noise generation in the picture signal can be prevented, which occurs because the predetermined stage of horizontal switch is turned on, at the moment the horizontal switch two stages prior to the predetermined stage is switched from the on state to off state. As a result, the picture deterioration caused by the noise of the picture signal. In addition, since the gate potential can be prevented from being lowered too much when the through-current flows between the second potential and the clock signal line, by connecting the high resistance between the gate of the first transistor and the clock signal line, the malfunction such that the first transistor which was held in off state is turned on can be prevented. Therefore, the output signal can be prevented from becoming unstable caused by the malfunction of the first transistor. As a result, the image deterioration caused by the unstable output signal of the shift register circuit can be prevented. In addition, the number of steps of ion implantations and the number of ion implantation masks can be reduced by forming the first transistor, the second transistor and the third transistor into the first conductivity type as compared with the case the shift register circuit comprising two kinds of conductivity types of transistors is formed. As a result, the manufacturing processes can be simplified and the manufacturing cost can be reduced.

### BRIEF DESCRIPTION OF THE DRAWINGS

FIG. 1 is a plan view showing a liquid crystal display according to a first embodiment of the present invention;

FIG. 2 is a circuit diagram showing a shift register circuit constituting a H driver of the liquid crystal display according to the first embodiment shown in FIG. 1;

FIG. 3 is a schematic view for explaining a structure of a p-channel transistor having two gate electrodes;

FIG. 4 is a timing chart of the shift register circuit of the H driver of the liquid crystal display according to the first embodiment shown in FIG. 2;

FIG. 5 is a plan view showing a liquid crystal display according to a second embodiment of the present invention;

FIG. 6 is a circuit diagram showing a shift register circuit constituting a H driver of the liquid crystal display according to the second embodiment of the present invention shown in FIG. 5;

FIG. 7 is a schematic view for explaining an n-channel transistor structure having two gate electrodes;

FIG. 8 is a timing chart of the shift register circuit of the H driver of the liquid crystal display according to the second embodiment shown in FIG. 6;

FIG. 9 is a plan view showing an organic EL display according to a third embodiment of the present invention;

FIG. 10 is a plan view showing an organic EL display according to a fourth embodiment of the present invention;

FIG. 11 is a circuit diagram showing an output-side circuit part of a shift register circuit constituting a H driver of a liquid crystal display according to a fifth embodiment of the present invention;

FIG. 12 is a circuit diagram showing an output-side circuit part of a shift register circuit constituting a H driver of a liquid crystal display according to a sixth embodiment of the present invention;

FIG. 13 is a circuit diagram of a conventional shift register circuit including a resistance loading type of an inverter circuit; and

FIG. 14 is a timing chart of the conventional shift register circuit shown in FIG. 13.

### DESCRIPTION OF THE PREFERRED EMBODIMENTS

Hereinafter, embodiments of the present invention are described with reference to the drawings.

### First Embodiment

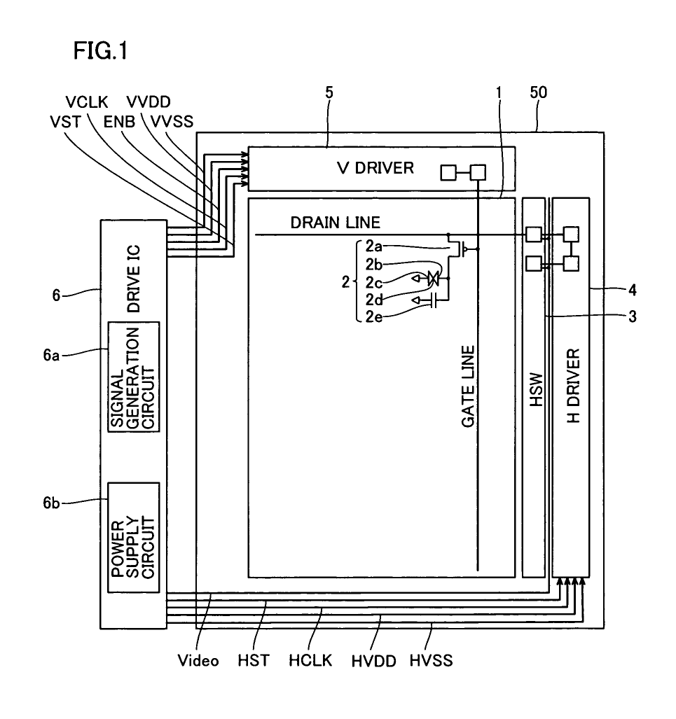

According to a first embodiment, a display part 1 is provided on a substrate 50 in FIG. 1. In addition, a constitution for one pixel is shown in the display part 1 in FIG. 1. Pixels 2 are arranged in the shape of a matrix in the display part 1. Each pixel 2 comprises a p-channel transistor 2a, a pixel electrode 2b, an opposite electrode 2c arranged so as to be opposed to the pixel electrode 2b, which is common to the pixel 2, a liquid crystal 2d sandwiched between the pixel electrode 2b and the opposite electrode 2c and an auxiliary capacitor 2e. A source of the p-channel transistor 2a is connected to a drain line and a drain is connected to the pixel electrode 2b and the auxiliary capacitor 2c. A gate of the p-channel transistor 2a is connected to a gate line.

In addition, a horizontal switch (HSW) 3 and a H driver 4 for driving (scanning) the drain line of the display part 1 are provided on the substrate 50 along one side of the display part 1. In addition, a V driver 5 for driving (scanning) the gate line of the display part 1 is provided on the substrate 50 along another side of the display part 1. Although only two of the horizontal switches 3 are shown in FIG. 1, they are arranged by the number corresponding to the number of pixels. In addition, referring to the H driver 4 and the V driver 5, although only two shift registers constituting them are shown in FIG. 1, they are arranged by the number corresponding to the number of pixels. A drive IC 6 is disposed outside of the substrate 50. The drive IC 6 comprises a signal generation circuit 6a and a power supply circuit 6b. A video signal Video, a start signal HST, a clock signal HCLK, a positive-side potential HVDD and a negative-side potential HVSS are supplied from the drive IC 6 to the H driver 4. A start signal VST, a clock signal VCLK, an enable signal ENB, a positive-side potential VVDD and a negative-side potential VVSS are supplied from the drive IC 6 to the V driver 5. In addition, the positive-side potential HVDD is an example of a “second potential” of the present invention and the negative-side potential HVSS is an example of a “first potential” of the present invention.

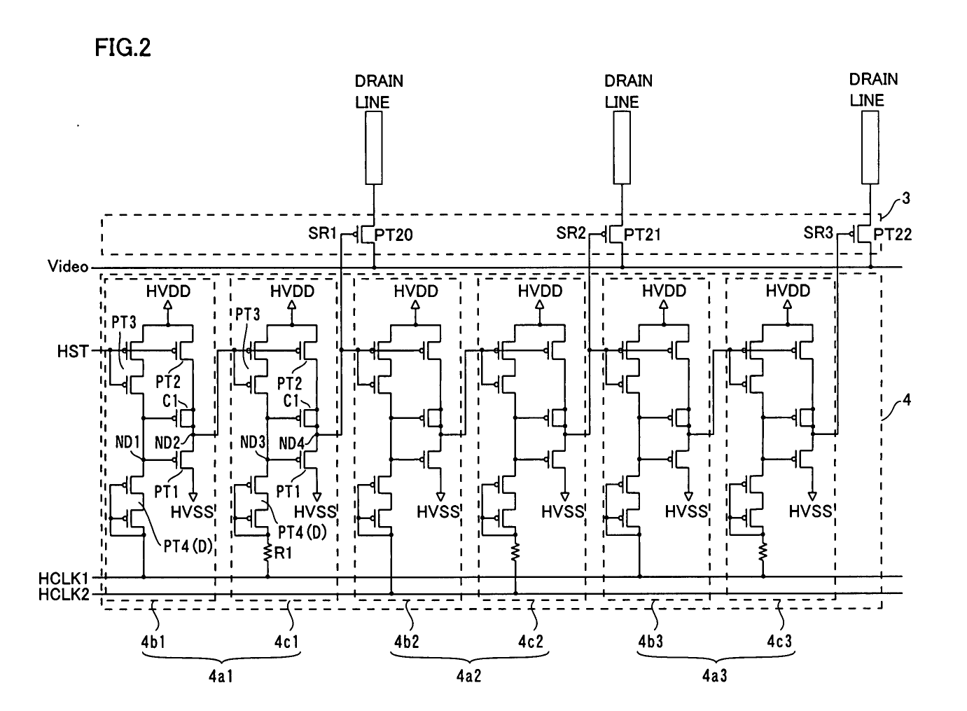

Referring to FIG. 2, a plural stages of shift register circuits 4a1, 4a2 and 4a3 are provided in the H driver 4. Although only three stages of shift register circuits 4a1, 4a2 and 4a3 are shown in FIG. 2 for simplification, they are provided by the number of stages corresponding to the number of pixels actually. The first stage of shift register circuit 4a1 comprises an input-side circuit part 4b1 and an output-side circuit part 4c1. The input-side circuit part 4b1 is an example of a “second circuit part” of the present invention and the output-side circuit part 4c1 is an example of a “first circuit part” of the present invention.

The input-side circuit part 4b1 of the first stage of shift register circuit 4a1 comprises p-channel transistors PT1, PT2 and PT3, a diode-connected p-channel transistor PT4, a capacitor C1 formed by connecting the source and the drain of the p-channel transistor. Similar to the input-side circuit part 4b1, the output-side circuit part 4c1 of the first stage of shift register circuit 4a1 comprises p-channel transistors PT1, PT2, PT3 and PT4 and a capacitor C1. The p-channel transistors PT1, PT2, PT3 and PT4 are examples of a “first transistor”, a “second transistor”, a “third transistor”, and a “fourth transistor” of the present invention, respectively.

Here, according to the first embodiment, the output-side circuit part 4c1 further comprises a high resistance R1 having a resistance value of about 100 kΩ which is different from the input-side circuit part 4b1.

According to the first embodiment, the p-channel transistors PT1 to PT4, and the p-channel transistor constituting the capacitor C1 provided in the input-side circuit part 4b1 and the output-side circuit part 4c1 are all constituted by TFT's (thin film transistor) consisting of p-type MOS transistors (field effect transistors). Hereinafter, the p-channel transistors PT1 to PT4 are simply referred to as transistors PT1 to PT4, respectively.

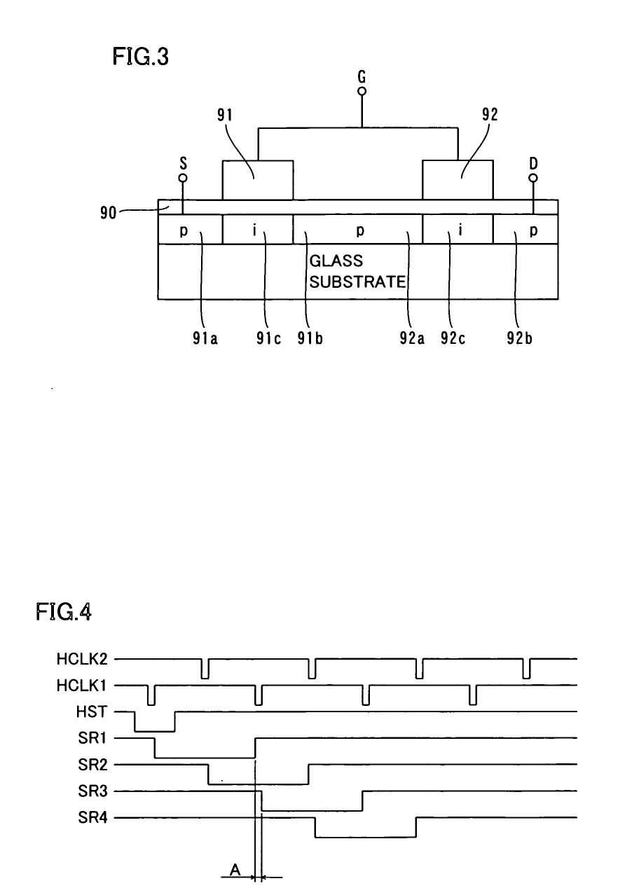

In addition, according to the first embodiment, the transistors PT3 and PT4 are formed so as to have two gate electrodes 91 and 92 electrically connected to each other, respectively as shown in FIG. 3. More specifically, one gate electrode 91 and the other gate electrode 92 are formed in one channel region 91c and in the other channel region 92c through a gate insulating film 90, respectively. Then, one channel region 91c is formed so as to be sandwiched between one source region 91a and one drain region 91b, and the other channel region 92c is formed so as to be sandwiched between the other source region 92a and the other drain region 92b. In addition, the drain region 91b and the source region 92a are constituted by a common impurity region.

As shown in FIG. 2, a source of the transistor PT 1 is connected a node ND 2 and a drain thereof is connected to the negative-side potential HVSS in the input-side circuit part 4b1. A gate of the transistor PT1 is connected to a node ND 1 and a clock signal HCLK1 is supplied to the gate of the transistor PT1. A source of the transistor PT2 is connected to the positive-side potential HVDD and a drain thereof is connected to the node ND2. The start signal HST is supplied to a gate of the transistor PT2.

According to the first embodiment, the transistor PT3 is connected between the gate of the transistor PT1 and the positive-side potential HVDD. The start signal HST is supplied to the gate of the transistor PT3. The transistor PT3 is provided in order to turn off the transistor PT1 when the transistor PT2 is in on state, whereby the transistors PT2 and PT1 are prevented from being turned on at the same time.

Furthermore, according to the first embodiment, the capacitor C1 is connected between the gate and the source of the transistor PT1. In addition, the diode-connected transistor PT4 is connected between the gate of the transistor PT1 and the clock signal line (HCLK1). A pulse voltage of the clock signal HCLK1 at H level is prevented from flowing back from the clock signal line (HCLK1) to the capacitor C1 by the diode-connected transistor PT4. On-resistance of the transistor PT4 is set so as to be lower than on-resistance of the transistor PT3.

The circuit constitution of the output-side circuit part 4c1 is the same as that of the input-side circuit part 4b1 basically except for including the high resistance R1. However, the source of the transistor PT1 and the drain of the transistor PT2 are connected to a node ND4, respectively in the output-side circuit part 4c1. The gate of the transistor PT1 is connected to a node ND3 and the clock signal HCLK1 is supplied to the gate of the transistor PT 1. The gates of the transistors PT2 and PT3 are connected to the node ND2 of the input-side circuit part 4b1.

Here, according to the first embodiment, the high resistance R1 is connected between the transistor PT4 and the clock signal line (HCLK1) in the output-side circuit part 4c1. The high resistance R1 is provided in order to slow response speed when the transistor PT1 is turned on. Thus, when the transistor PT1 is in on state, the signal output from the output-side circuit part 4c1 is slowed and when the transistor PT 1 is in off state, the signal output from the output-side circuit part 4c1 is quickened.

An output signal SR1 of the first stage of shift register circuit 4a1 is output from the node ND4 (output node). The output signal SR1 is supplied to the horizontal switch 3. The horizontal switch 3 includes a plurality of transistors PT20, PT21 and PT22. In addition, although only three transistors PT20, PT21 and PT22 are shown in FIG. 2 for simplification, they are provided by the number corresponding to the number of pixels actually. Gates of the transistors PT20, PT21 and PT22 are connected to outputs SR1, SR2 and SR3 of the first to third stages of shift register circuits 4a1 through 4a3, respectively. In addition, drains of the transistors PT20, PT21 and PT22 are connected to respective stages of drain lines. Sources of the transistors PT20, PT21 and PT22 are connected to one video signal line (Video), respectively.

Furthermore, the second stage of shift register circuit 4a2 is connected to the node ND4 (output node) of the first stage of shift register circuit 4a1. The second stage of shift register circuit 4a2 comprises an input-side circuit part 4b2 and an output-side circuit part 4c2. Circuit constitutions of the input-side circuit part 4b2 and the output-side circuit part 4c2 of the second stage of shift register circuit 4a2 is the same as the circuit constitutions of the input-side circuit part 4b1 and the output-side circuit part 4c1 of the first stage of shift register circuit 4a1. The output signal SR2 is output from the output node of the second stage of shift register circuit 4a2.

In addition, the third stage of shift register circuit 4a3 is connected to the output node of the second stage of shift register circuit 4a2. The third stage of shift register circuit 4a3 comprises an input-side circuit part 4b3 and an output-side circuit part 4c3. The circuit constitutions of the input-side circuit part 4b3 and the output-side circuit part 4c3 of the third stage of shift register circuit 4a3 is the same as the circuit constitutions of the input-side circuit part 4b1 and the output-side circuit part 4c1 of the first stage of shift register circuit 4a1. The output signal SR3 is output from the output node of the third stage of shift register circuit 4a3. The outputs SR1 to SR3 of the shift register circuits 4a1 to 4a3 are input to the source of the horizontal switch 3 provided so as to correspond to the number of the video signal lines (for example, when three kinds of video signals Video, such as red (R), green (G) and blue (B) are input, the number is three).

A fourth stage of shift register circuit (not shown) is connected to the output node of the third stage of shift register circuit 4a3. The circuit constitution of the fourth or later stage of shift register circuit is the same as that of the first stage of shift register circuit 4a1. In addition, the latter stage of shift register circuit is connected to the output node of the former stage of shift register circuit.

A clock signal line (HCLK2) is connected to the second stage of shift register circuit 4a2. In addition, similar to the first stage of shift register circuit 4a1, the clock signal line (HCLK1) is connected to the third stage of shift register circuit 4a3. Thus, the clock signal line (HCLK1) and the clock signal line (HCLK2) are alternatively connected to the plural stages of shift register circuits.

Next, a description is made of an operation of the shift register circuit of the H driver of a liquid crystal display according to the first embodiment with reference to FIGS. 2 and 4. Referring to FIG. 4, reference numerals SR1, SR2, SR3 and SR4 designate output signals from the first, second, third and fourth stages of shift register circuits, respectively.

First, as an initial state, the start signal HST at H level (HVDD) has been input to the input-side circuit part 4b1 of the first stage of shift register circuit 4a1, whereby the transistors PT2 and PT3 of the input-side circuit part 4b1 are turned off and the transistor PT1 is turned on, so that a potential of the node ND2 is at L level. Therefore, in the output-side circuit part 4c1, the transistors PT2 and PT3 are turned on. Thus, since the potential of the node ND3 becomes H level, the transistor PT1 is turned off. Thus, in the output-side circuit part 4c1, since the transistor PT2 is turned on and the transistor PT1 is turned off, the node ND4 becomes H level. Thus, in the initial state, the output signal SR1 at H level is output from the first stage of shift register circuit 4a1.

When the start signal HST at L level (HVSS) is input in the state the output signal SR1 at H level is output from the first stage of shift register circuit 4a1, the transistors PT2 and PT3 are turned on in the input-side circuit part 4b1, whereby since both nodes ND1 and ND2 become H level, the transistor PT1 is turned off. Thus, since the potential of the node ND2 becomes H level, the transistors PT2 and PT3 are turned off in the output-side circuit part 4c1. At this time, since the potential of the node ND3 is held at H level, the transistor PT1 is held in off state. Therefore, since the node ND4 is held at H level, the output signal SR1 at H level is output from the first stage of shift register circuit 4a1.

Then, the clock signal HCLK1 at L level (HVSS) is input through the transistor PT4 in the input-side circuit part 4b1. At this time, since the transistor PT3 is in on state, the potential of the node ND1 is held at H level. Thus, the p-channel transistor PT1 is held in off state.

Meanwhile, in the output-side circuit part 4c1 also, the clock signal HCLK1 at L level (HVSS) is input through the high resistance R1 and the transistor PT4. At this time, since the transistor PT3 is in off state, the potential of the node ND3 becomes L level, whereby the p-channel transistor PT1 if turned on. In addition, while the clock signal CLK1 is at L level, a voltage corresponding to the clock signal HCLK1 at L level is charged to the capacitor C1.

At this time, according to the first embodiment, the response speed when the transistor PT1 is turned on is slowed because of the high resistance R1 in the output-side circuit part 4c1.

At this time, since the transistor PT2 is in off state in the output-side circuit part 4c1, the potential of the node ND 4 is lowered to the HVSS side through the transistor PT1 which is in on state. In this case, the potential of the node ND3 (gate potential of the transistor PT1) is lowered in accordance with the lowering of the potential of the node ND4 (source potential of the transistor PT1) such that the voltage between the gate and the source of the transistor PT1 may be maintained by the capacitor C1. In addition, since the transistor PT3 is in off state and the signal at H level from the clock signal line (HCLK1) does not flow back to the node ND3 in the diode-connected transistor PT4, the voltage held by the capacitor C1 (voltage between the gate and the source of the transistor PT1) is maintained. Thus, since the transistor PT1 is constantly held in on state when the potential of the node ND4 is lowered, the potential of the node ND4 is lowered to HVSS. As a result, the output signal SR1 at L level is output from the first stage of shift register circuit 4a1.

At this time, according to the first embodiment, in the output-side circuit part 4c1, since the response speed when the transistor PT1 becomes on is slowed, the output signal SR1 output from the first stage of shift register circuit 4a1 (output-side circuit part 4c1) is delayed.

In addition, in the output-side circuit part 4c1, the potential of the node ND 3 when the potential of the node ND4 was lowered to HVSS is lower than HVSS. Therefore, a bias voltage applied to the transistor PT3 connected to the positive-side potential HVDD is higher than a potential difference between HVDD and HVSS. In addition, when the clock signal HCLK1 becomes H level (HVDD), a bias voltage applied to the transistor PT4 connected to the clock signal line (HCLK1) becomes higher than the potential difference between HVDD and HVSS.

Then, in the input-side circuit part 4b1, when the start signal HST at H level (HVDD) is input, the transistors PT2 and PT3 are turned off. In this case, the nodes ND1 and ND2 become a floating state while held at H level. Therefore, since an influence is not applied to another part, the output signal SR1 at L level from the first stage of shift register circuit 41a is maintained.

Then, in the input-side circuit part 4b1, the clock signal HCLK1 at L level (HVSS) is input again through the transistor PT4. Thus, since the transistor PT1 is turned on, the potential of the node ND2 is lowered to the HVSS. In this case, since the transistor PT1 is constantly held in on state when the potential of the node ND2 is lowered by functions of the transistor PT4 and the capacitor C1, the potential of the node ND2 is lowered to HVSS. Therefore, the transistor PT2 and PT3 of the output-side circuit part 4c1 are turned on.

At this time, according to the first embodiment, since the transistor PT1 is turned off by the transistor PT3 in the output-side circuit part 4c1, the transistors PT1 and PT2 are prevented from being turned on at the same time. Thus, a through-current is prevented from flowing between HVDD and HVSS through the transistors PT1 and PT2. In addition, the response speed when the transistor PT1 is turned off becomes faster than the response speed when the transistor PT1 is turned on.

Thus, in the output-side circuit part 4c1, the transistor PT2 is turned on and the transistor PT1 is turned off, whereby the potential of the node ND 4 is heightened from HVSS to HVDD and becomes H level. Therefore, the output signal SR1 at H level is output from the first stage of shift register circuit 4a1. At this time, when the clock signal HCLK1 at L level is input, a through-current flows between the clock signal line (HCLK1) and HVDD through the transistors PT4 and PT3 and the high resistance R1.

At this time, according to the first embodiment, the output signal SR1 at H level output from the first stage of shift register circuit 4a1 (output-side circuit part 4c1) is quickened as compared with the case the output signal SR1 at L level is output.

As described above, according to the first stage of shift register circuit 4a1 of the first embodiment, when the clock signal HCLK1 at L level is input in the state the start signal HST at L level is input to the input-side circuit part 4b1, the output signal SR1 at L level is output from the output-side circuit part 4c1. Then, when the clock signal HCLK1 at L level is input again in the state the output signal SR1 at L level is output from the output-side circuit part 4c1, the output signal SR1 from the output-side circuit part 4c1 becomes H level.

In addition, the output signal SR1 of the first stage of shift register circuit 4a1 is input to the input-side circuit part 4b2 of the second stage of shift register circuit 4a2. In the second stage of shift register circuit 4a2, when the clock signal HCLK2 at L level is input in the state the output signal SR1 at L level of the first stage of shift register circuit 4a1 is input to the input-side circuit part 4b2, the output signal SR2 at L level is output from the output-side circuit part 4c2. Furthermore, when the clock signal HCLK1 at L level is input in the state the output signal SR2 at L level of the second stage of shift register circuit 4a2 is input to the input-side circuit part 4b3, the output signal SR3 at L level is output from the output-side circuit part 4c3. Thus, the output signal is input fro the former stage of shift register circuit to the next stage of shift register circuit and the clock signals HCLK1 and HCLK2 whose timings when become L level are shifted are alternately input to each stage of shift register circuit. Thus, the timing the output signal at L level is output from each stage of shift register circuit is shifted.

When the output signals at L level whose timings are shifted are input to the gates of the transistors PT20, PT21 and PT22 of the horizontal switch 3, the transistors PT20, PT21 and PT22 are sequentially turned on. Thus, since the video signal Video is supplied from the video signal line (Video) to each stage of drain line, each stage of drain line is sequentially driven (scanned). When scanning for all stages of drain lines connected to one gate line is finished, the next gate line is selected. Then, each stage of drain line is sequentially scanned and then the next gate line is selected. This operation is repeated until scanning of each stage of drain line connected to the last gate line is completed, whereby scanning for one screen is finished.

According to the first embodiment, as describe above, since the response speed when the transistor PT1 is turned on is slowed by connecting the high resistance R1 between the transistor PT4 of each of the output-side circuit parts (4c1, 4c2 and 4c3) and the clock signal line (HCLK), the output signals (SR1, SR2 and SR3) output from the shift register circuits (4a1, 4a2 and 4a3) can be delayed when the transistors PT1 are in on state. Here, according to the first embodiment, since the resistance value of the high resistance R1 is set at about 100 kΩ, the shift amount (A in FIG. 4) of timing between the output signal when the transistor PT1 is in on state and the output signal when the PT1 is off state is more than about 20 nsec. In this case, when it is assumed that the transistor PT1 of the first stage of shift register circuit 4a1 is turned off (SR1 is at H level) while the transistor PT1 of the third stage of shift register circuit 4a3 is in on state (SR3 is at L level), the response speed of the transistor PT22 corresponding to the third stage of shift register circuit 4a3 is slowed and the response speed of the transistor PT20 corresponding to the first stage of shift register circuit 4a1 is quickened. Thus, the moment the third stage of transistor PT22 is switched from off state to on state and the moment the first stage of transistor PT20 is switched from the on state to off state can be prevented from overlapping with each other. Therefore, since the third stage of transistor PT22 can be turned on after the first stage of transistor PT20 was turned off, at the moment the first transistor PT20 is switched from on state to off state, the third stage of transistor PT22 is turned on. As a result, a noise is prevented from being generated in the video signal Video, so that an image is prevented from deteriorating by the noise of the video signal Video.

In addition, since the high resistance R1 is connected between the transistor PT4 of each of the output-side circuit parts (4c1, 4c2 and 4c3) and the clock signal line (HCLK), a malfunction such that the transistor PT1 held in off state becomes on state because the potential of the node ND3 is lowered too much when the through-current flows between the HVDD and the clock signal line (HCLK) can be prevented. Therefore, the problem that the output signals (SR1, SR2 and SR3) of the shift register circuits (4a1, 4a2 and 4a3) become unstable because of the malfunction of the transistor PT1 can be prevented. As a result, the image deterioration caused by the unstable output signal of the shift register circuit can be prevented.

In addition, according to the first embodiment, charging speed is prevented from being lowered when the voltage corresponding to the clock signal HCLK at L level is charged to the capacitor C1, by reducing the on-resistance of the transistor PT4 so as to be lower than the on-resistance of the transistor PT3.

In addition, according to the first embodiment, the number of steps of ion implantations and the number of ion implantation masks can be reduced by constituting the transistors PT1 to PT4 and the transistor constituting the capacitor C1 with the TFT's (thin film transistors) comprising the p-type MOS transistors (field effect transistors), as compared with the case the shift register circuit comprising two kinds of conductivity types of transistors is formed. Thus, the manufacturing processes can be simplified and the manufacturing cost can be reduced. In addition, since it is not necessary to constitute the p-type field effect transistor with LDD (Lightly Doped Drain) unlike the n-type field effect transistor, the manufacturing processes can be further simplified.

Furthermore, according to the first embodiment, since the transistor PT3 connected between the gate of the transistor PT1 and the positive-side potential HVDD is constituted so as to have two gate electrodes 91 and 92 electrically connected to each other, the voltage applied to the transistor PT3 is distributed to between the source and the drain corresponding to one gate electrode 91 and between the source and the drain corresponding to the other gate electrode 92 by almost half-and-half (a distributed ratio depends on a transistor size and the like). Therefore, even when the bias voltage applied to the transistor PT3 becomes higher than the potential difference between HVSS and HVDD, the voltage lower than the potential difference between HVSS and HVDD is applied between the source and the drain corresponding to one gate electrode 91 of the transistor PT3 and between the source and the drain corresponding to the other gate electrode 92, respectively. Thus, since the problems such that the characteristics of the transistor PT3 deteriorates because the bias voltage higher than the potential difference between HVSS and HVDD is applied to the transistor PT3 can be prevented, the scanning characteristics of the liquid crystal display comprising the H driver 4 having the shift register circuits 4a1, 4a2 and 4a3 is prevented from being lowered.

In addition, according to the first embodiment, since the transistor PT4 connected between the gate of the transistor PT1 and the clock signal line (HCLK) is also constituted so as to have the gate electrodes 91 and 92 electrically connected to each other, like the above transistor PT3, even when the bias voltage applied to the transistor PT4 becomes higher than the potential difference between HVSS and HVDD, the characteristics of the transistor PT4 can be prevented from deteriorating. As a result, the problem such that the scanning characteristics of the liquid crystal display comprising the H driver 4 having the shift register circuits 4a1, 4a2 and 4a3 deteriorate because the characteristics of the transistor PT4 deteriorates, can be also prevented.

### Second Embodiment

According to a second embodiment, a description is made of an example in which a H driver for driving (scanning) a drain line is constituted by an n-channel transistor.

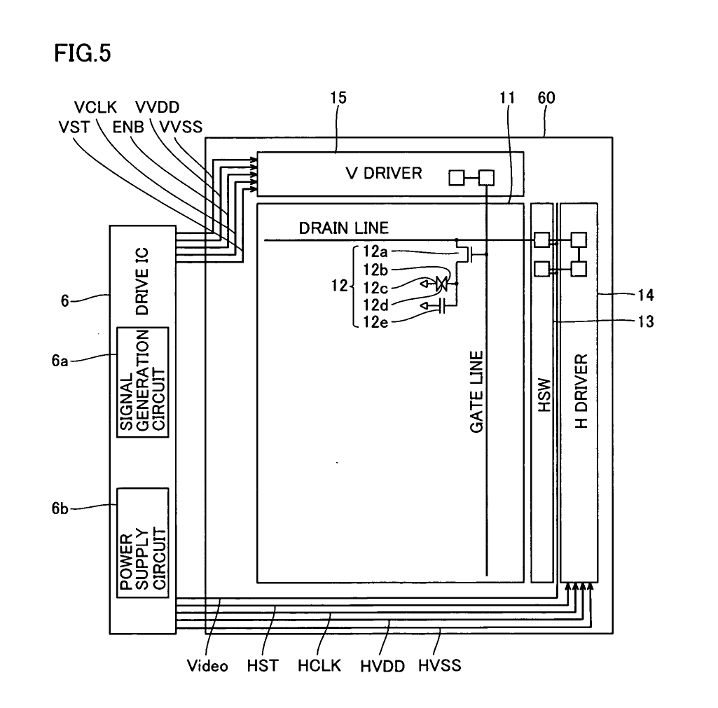

Referring to FIG. 5, a display part 11 is provided on a substrate 60 in a liquid crystal display in the second embodiment. A constitution for one pixel is shown in the display part 11 in FIG. 5. In addition, each pixel 12 arranged in the shape of a matrix in the display part 11 comprises an n-channel transistor 12a, a pixel electrode 12b, and an opposite electrode 12c arranged so as to be opposed to the pixel electrode 12b, which is common to each pixel 12, a liquid crystal 12d sandwiched between the pixel electrode 12b and the opposite electrode 12c and an auxiliary capacitor 12e. A source of the n-channel transistor 12a is connected to the pixel electrode 12b and the auxiliary capacitor 12c and a drain thereof is connected to a drain line. A gate of the n-channel transistor 12a is connected to a gate line. In addition, a horizontal switch (HSW) 13 and a H driver 14 for driving (scanning) the drain line of the display part 11 are provided on the substrate 60 along one side of the display part 11. In addition, a V driver 15 for driving (scanning) the gate line of the display part 11 is provided on the substrate 60 along another side of the display part 11. Although only two of the horizontal switches 13 are shown in FIG. 5, they are arranged by the number corresponding to the number of pixels. In addition, referring to the H driver 14 and the V driver 15, although only two shift registers constituting them are shown in FIG. 5, they are arranged by the number corresponding to the number of pixels.

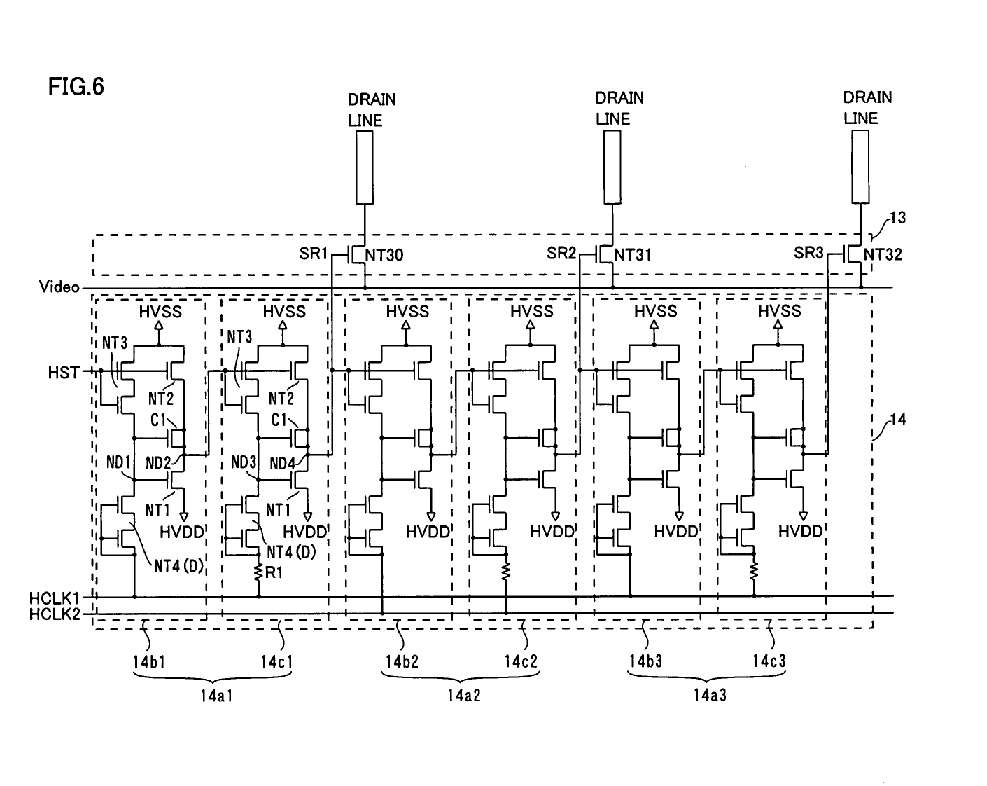

In addition, as shown in FIG. 6, a plural stages of shift register circuits 14a1, 14a2 and 14a3 are provided in the H driver 14. Although only three stages of shift register circuits 14a1, 14a2 and 14a3 are shown in FIG. 6 for simplification, they are provided by the number of stages corresponding to the number of pixels actually. The first stage of shift register circuit 14a1 comprises an input-side circuit part 14b1 and an output-side circuit part 14c1. The input-side circuit part 14b1 is an example of a “second circuit part” of the present invention and the output-side circuit part 14c1 is an example of a “first circuit part” of the present invention.

The input-side circuit part 14b1 of the first stage of shift register circuit 14a1 comprises n-channel transistors NT1, NT2 and NT3, a diode-connected n-channel transistor NT4, a capacitor C1 formed by connecting the source and the drain of the n-channel transistor. Similar to the input-side circuit part 14b1, the output-side circuit part 14c1 of the first stage of shift register circuit 14a1 comprises n-channel transistors NT1, NT2, NT3 and NT4 and a capacitor C1. The n-channel transistors NT1, NT2, NT3 and NT4 are examples of a “first transistor”, a “second transistor”, a “third transistor”, and a “fourth transistor” of the present invention, respectively.

Here, according to the second embodiment, the output-side circuit part 14c1 further comprises a high resistance R1 having a resistance value of about 100 kΩ which is different from the input-side circuit part 14b1.

According to the second embodiment, the n-channel transistors NT1 to NT4, and then-channel transistor constituting the capacitor C1 provided in the input-side circuit part 14b1 and the output-side circuit part 14c1 are all constituted by TFT's (thin film transistor) consisting of n-type MOS transistors (field effect transistors). Hereinafter, the n-channel transistors NT1 to NT4 are simply referred to as transistors NT1 to NT4, respectively.

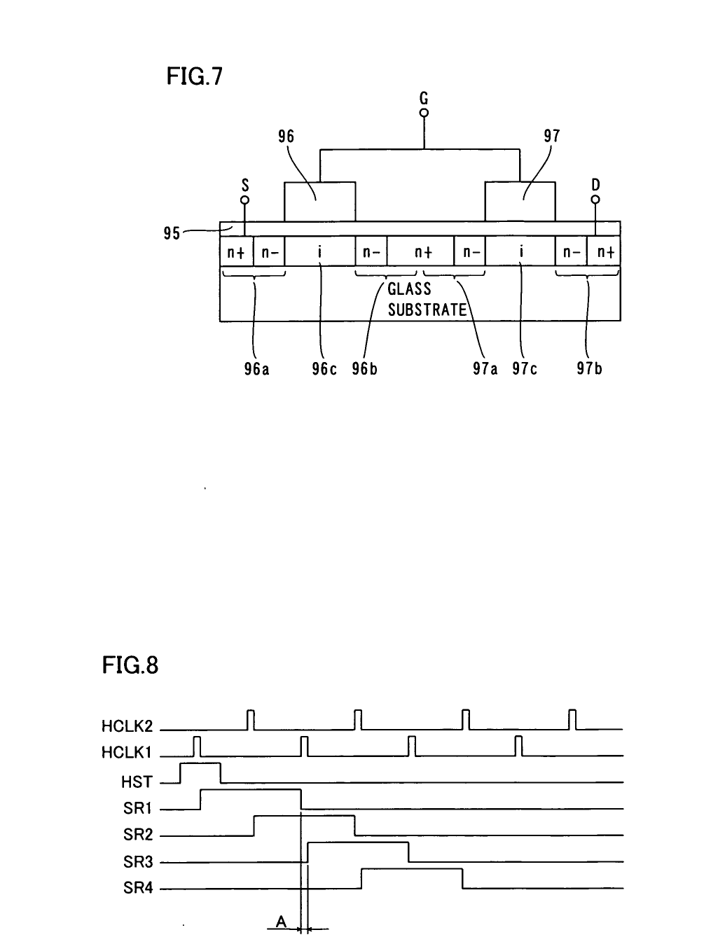

According to the second embodiment, the transistors NT3 and NT4 are formed so as to have two gate electrodes 96 and 97 electrically connected to each other, respectively as shown in FIG. 7. More specifically, one gate electrode 96 and the other gate electrode 97 are formed in one channel region 96c and in the other channel region 97c through a gate insulating film 95, respectively. Then, one channel region 96c is formed so as to be sandwiched between one source region 96a of a LDD (Lightly Doped Drain) structure having a low-concentration impurity region and high-concentration impurity region, and one drain region 96b of the LDD structure, and the other channel region 97c is formed so as to be sandwiched between the other source region 97a of the other LDD structure and the other drain region 97b of the other LDD structure. In addition, the drain region 96b and the source region 97a have a common high-concentration impurity region.

As shown in FIG. 6, the transistors NT1 to NT4, the capacitor C1 and the high resistance R1 of the second embodiment are connected to positions corresponding to the transistors PT1 to PT4, the capacitor C1 and the high resistance R1 of the first embodiment shown in FIG. 2. In other words, according to the second embodiment, the high resistance R1 is connected between the transistor NT4 of the output-side circuit part 14c1 and a clock signal line (HCLK1). However, sources of the transistor NT2 and NT3 are connected to negative-side potential HVSS, respectively and a drain of the transistor NT1 is connected to positive-side potential HVDD. In addition, the negative-side potential HVSS is an example of a “second potential” of the present invention and the positive-side potential HVSS is an example of a “first potential” of the present invention.

The constitution of the shift register circuit 14a1 of the second embodiment other than the above is the same as the shift register circuit 4a1 (cf. FIG. 2) of the first embodiment.

In addition, the second stage of shift register circuit 14a2 comprises an input-side circuit part 14b2 and an output-side circuit part 14c2, and the third stage of shift register circuit 14a3 comprises an input-side circuit part 14b3 and an output-side circuit part 14c3. The circuit constitutions of the second stage and third stage of shift register circuits 14a2 and 14a3 are the same as that of the first shift register circuit 14a1.

In addition, a horizontal switch 13 includes a plurality of transistors NT30, NT31 and NT32. In addition, although only three transistors NT30, NT31 and NT32 are shown for simplification in FIG. 6, they are provided by the number corresponding to the number of pixels actually. Gates of the transistors NT30, NT31 and NT32 are connected to outputs SR1, SR2 and SR3 of the first to third stages of shift register circuits 14a1 to 14a3, respectively. In addition, sources of transistors NT30, NT31 and NT32 are connected to respective stages of the drain lines. Drains of the transistors NT30, NT31 and NT32 are connected to one video signal line (Video), respectively. In addition, when three kinds of video signals Video such as red (R), green (G) and blue (B) are input, the number of the video signal lines is three.

Referring to FIG. 8, in the shift register circuit according to the second embodiment, signals having waveforms provided by inverting H level and L level of the clock signals HCLK1 and HCLK2 and the start signal HST in the timing chart of the shift register circuit according to the first embodiment shown in FIG. 4 are input as clock signals HCLK1 and HCLK2 and the start signal HST. Thus, signals having waveforms provided by inverting the H level and L level of the output signals SR1 to SR4 from the shift register circuits according to the first embodiment shown in FIG. 4 are output from the shift register circuits according to the second embodiment. Thus, according to the second embodiment, because of the high resistance R1 having the same value of about 100 kΩ as in the first embodiment, the shift amount (A in FIG. 8) of timing between the output signal when the transistor NT1 is in on state and the output signal when the NT1 is off state is more than about 20 nsec. Thus, the moment the third stage of transistor NT32 is switched from off state to on state and the moment the first stage of transistor PT30 is switched from on state to off state are prevented from overlapping with each other. An operation of the shift register circuit according to the second embodiment other than the above is the same as that of the shift register circuit according to the first embodiment.

According to the second embodiment, as described above, since the high resistance R1 is connected between the transistor of each of the output-side circuit parts (14c1, 14c2 and 14c3) and the clock signal line (HCLK), there is provided the same effect as in the first embodiment such that an image of a liquid crystal display can be prevented from deteriorating.

### Third Embodiment

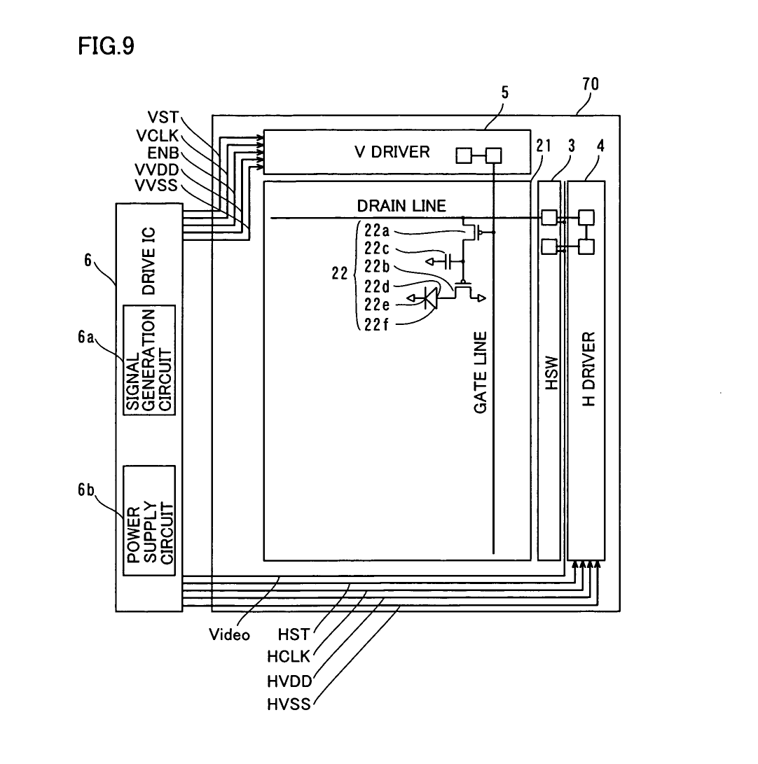

According to a third embodiment, description is made of an example in which the present invention is applied to an organic EL display with reference to FIG. 9.

As shown in FIG. 9, according to the organic EL display of the third embodiment, a display part 21 is provided on a substrate 70. A constitution for one pixel is shown in the display part 21 in FIG. 9. In addition, each pixel 22 arranged in the shape of a matrix in the display part 21 comprises two p-channel transistors 22a and 22b (referred to as transistors 22a and 22b hereinafter), an auxiliary capacitor 22c, an anode 22d and a cathode 22e, and an organic EL element 22f sandwiched between the anode 22d and the cathode 22e. A gate of the transistor 22a is connected to a gate line. A source of the transistor 22a is connected to a drain line. In addition, the auxiliary capacitor 22c and the gate of the transistor 22b is connected to a drain of the transistor 22a. Furthermore, a drain of the transistor 22b is connected to the anode 22d. Still further, a circuit constitution in a H driver 4 is the same as that of the H driver 4 in the shift register circuit using the p-channel transistor shown in FIG. 2. The constitution of the organic El display according to the third embodiment other than the above is the same as the liquid crystal display according to the first embodiment shown in FIG. 1.

Like the first embodiment, in the third embodiment, there can be also provided the same effect as in the first embodiment such that an image is prevented from deteriorating in the organic El display by connecting a high resistance R1 between the transistors PT4 of each of the output-side circuit parts (4c1, 4c2 and 4c3) and a clock signal line (HCLK).

### Fourth Embodiment

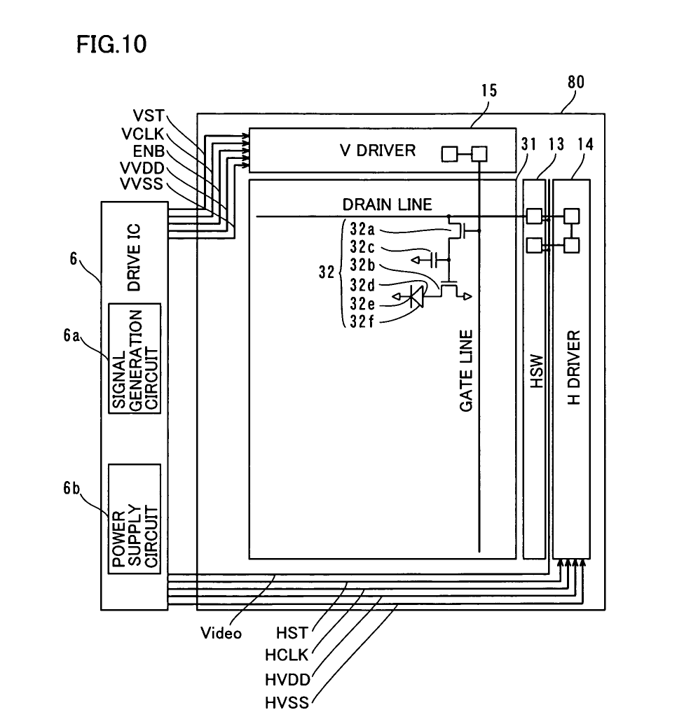

According to a fourth embodiment, description is made of an example in which the present invention is applied to an organic EL display with reference to FIG. 10.

As shown in FIG. 10, according to the organic EL display of the fourth embodiment, a display part 31 is provided on a substrate 80. A constitution for one pixel is shown in the display part 31 in FIG. 10. In addition, each pixel 32 arranged in the shape of a matrix in the display part 31 comprises two n-channel transistors 32a and 32b (referred to as transistors 32a and 32b hereinafter), an auxiliary capacitor 32c, an anode 32d and a cathode 32e, and an organic EL element 32f sandwiched between the anode 32d and the cathode 32e. A gate of the transistor 32a is connected to a gate line. A drain of the transistor 32a is connected to a drain line. In addition, the auxiliary capacitor 32c and the gate of the transistor 32b are connected to a source of the transistor 32a. Furthermore, a source of the transistor 32b is connected to the anode 32d. Still further, a circuit constitution in a H driver 14 is the same as that of the H driver 4 in the shift register circuit using the n-channel transistor shown in FIG. 6. The constitution of the organic El display according to the fourth embodiment other than the above is the same as the liquid crystal display according to the second embodiment shown in FIG. 5.

Like the second embodiment, in the fourth embodiment, there can be also provided the same effect as in the second embodiment such that an image is prevented from deteriorating in the organic El display by connecting a high resistance R1 between the transistors PT4 of each of the output-side circuit parts (14c1, 14c2 and 14c3) and a clock signal line (HCLK).

### Fifth Embodiment

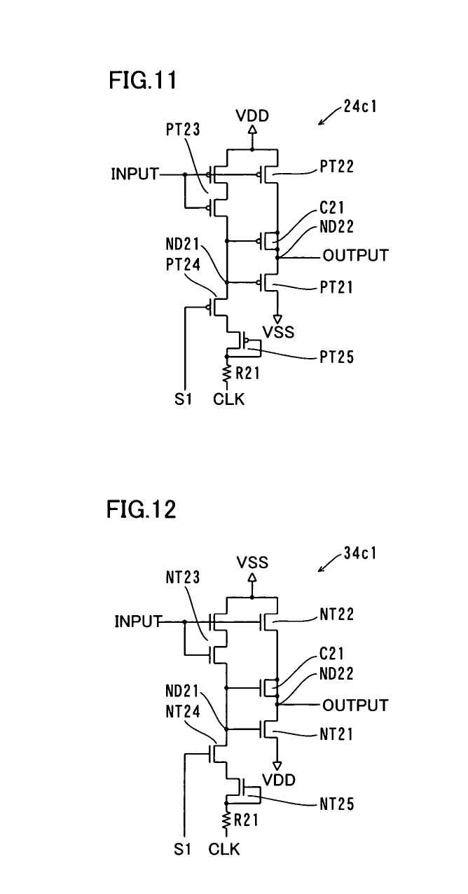

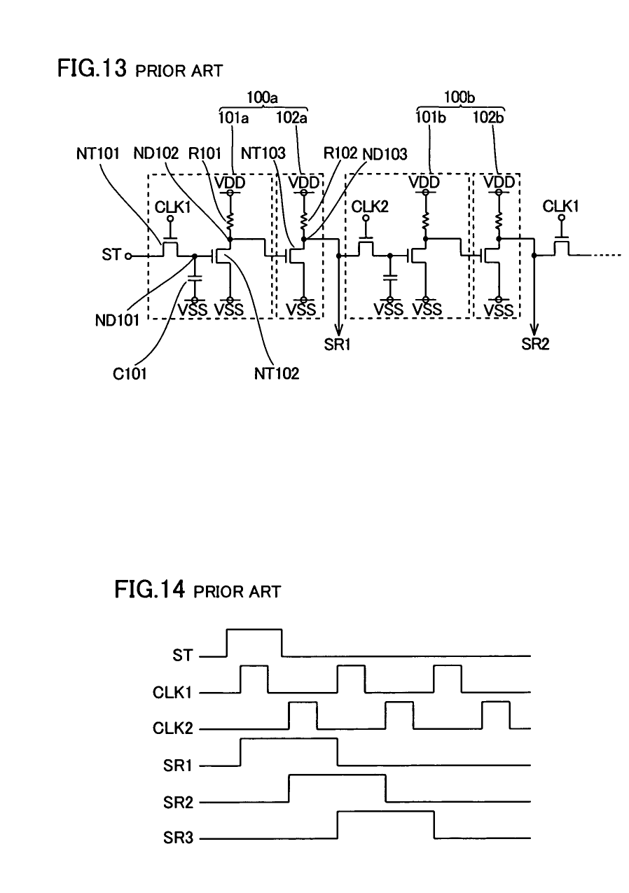

Referring to FIG. 11, according to a fifth embodiment, a description is made of a shift register circuit which can prevent an image deterioration caused by a noise of a picture signal and also can prevent a through-current.

More specifically, as shown in FIG. 11, an output-side circuit part 24c1 of a shift register circuit constituting a H driver of a liquid crystal display according to the fifth embodiment comprises transistors PT21, PT22, PT23 and PT24, a diode-connected transistor PT25 and a capacitor C21 formed by connecting the source and the drain of the transistor. The output-side circuit part 24c1 is an example of a “first circuit part” in the present invention. In addition, the transistors PT21, PT22, PT23 and PT24 are examples of a “first transistor”, a “second transistor”, a “third transistor” and a “fourth transistor” in the present invention.

Here, according to the fifth embodiment, the output-side circuit part 24c1 further comprises a high resistance R21 having a resistance value of about 100 kΩ.

According to the fifth embodiment, the p-channel transistors PT21 to PT25, and the p-channel transistor constituting the capacitor C21 are all constituted by TFT's (thin film transistor) consisting of p-type MOS transistors (field effect transistors).

In addition, according to the fifth embodiment, the transistor PT23 is formed so as to have two gate electrodes electrically connected to each other, like the first embodiment shown in FIG. 3.

As shown in FIG. 11, a source of the transistor PT21 is connected to a node ND22 and a drain is connected to the negative-side potential VSS. The gate of the transistor PT21 is connected to a node ND21 and a clock signal CLK is supplied to the gate of the transistor PT21. A source of the transistor PT22 is connected to a positive-side potential VDD and a drain is connected to the node ND22. An input signal is supplied to the gate of the transistor PT22.

According to the fifth embodiment, the transistor PT23 is connected between the gate of the transistor PT21 and the positive-side potential VDD. The input signal is supplied to the gate of the transistor PT23. The transistor PT23 is provided in order to turn off the transistor PT21 when the transistor PT22 is in on state, whereby the transistors PT21 and PT22 are prevented from being turned on at the same time.

Furthermore, according to the fifth embodiment, the transistor PT24 is connected between the gate of the transistor PT21 and a clock signal line (CLK). A signal S1 by which a period of on state which does not overlap with a period of on state of the transistor PT23 can be provided is supplied to the gate of the transistor PT24. In addition, the transistor PT25 is connected between the transistor PT24 and the clock signal line (CLK). Furthermore, the capacitor C21 is connected between the gate and the source of the transistor PT21.

In addition, according to the fifth embodiment, a high resistance R21 is connected between the transistor PT25 and the clock signal line (CLK). The high resistance R21 is provided in order to slow the response speed when the transistor PT21 is turned on. As a result, the signal output from the output-side circuit part 24c1 when the transistor PT21 is in on state is delayed and the signal output from the output-side circuit part 24c1 when the transistor PT21 is in off state is quickened.

According to an operation of the shift register circuit of the liquid crystal display of the fifth embodiment, when the input signal becomes H level, the transistors PT22 and PT23 are turned off. In addition, when the clock signal CLK becomes L level, the transistor PT25 is turned on. At this time, the signal S1 by which the period of on state which does not overlap with the period of on state of the transistor PT23, is supplied to the gate of the transistor PT24. As a result, since the transistor PT24 is turned on and the potential of the node ND21 is lowered, the transistor PT21 is turned on. In addition, while the cock signal CLK is at L level, a voltage corresponding to the clock signal CLK at L level is charged to the capacitor C21.

At this time, according to the fifth embodiment, the response speed when the transistor PT21 is turned on is slowed by the high resistance R21.

Since the transistor PT22 is in off state at this time, the potential of the node ND22 is lowered to the side of VSS through the on-state transistor PT21. In this case, the potential of the node ND21 (the gate potential of the transistor PT21) is lowered in accordance with the lowering of the potential of the node ND22 (source potential of the transistor PT21) such that the voltage between the gate and the source of the transistor PT21 may be maintained by the capacitor C21. In addition, since the transistor PT23 is in off state and the signal at H level from the clock signal line (CLK) does not flow back to the node ND21 in the diode-connected transistor PT25, the voltage held by the capacitor C21 (voltage between the gate and the source of the transistor PT21) is maintained. Thus, since the transistor PT21 is constantly held in on state when the potential of the node ND22 is lowered, the potential of the node ND22 is lowered to VSS. As a result, the output signal at L level is output from the output-side circuit part 24c1.

At this time, according to the fifth embodiment, since the response speed when the transistor PT21 becomes on state is slowed, the output signal output from the output-side circuit part 24c1 is delayed.

In addition, the potential of the node ND21 when the potential of the node ND22 is lowered to VSS is lower than VSS. Therefore, a bias voltage applied to the transistor PT23 connected to the positive-side potential VDD is higher than a potential difference between VDD and VSS.

Then, when the input signal becomes L level, the transistors PT22 and PT23 are turned on. At this time, according to the fifth embodiment, the transistor PT24 is turned off. In other words, the transistor PT23 and PT24 are not turned on at the same time. As a result, the through-current is prevented from flowing between VDD and the clock signal line (CLK) through the transistors PT23 and PT24.

In addition, according to the fifth embodiment, when the potential of the node ND21 is raised to H level through the on-state transistor PT23, the transistor PT21 is turned off. As a result, the through-current is prevented from flowing between VDD and VSS through the transistors PT21 and PT22.

AT this time, according to the fifth embodiment, the response speed when the transistor PT21 is turned off is faster than that when the transistor PT21 is turned on.

Then, when the transistor PT22 is turned on and the transistor PT21 is turned off, the potential of the node ND22 becomes H level from VSS to VDD. Therefore, the output signal at H level is output from the output-side circuit part 24c1.

At this time, according to the fifth embodiment, the output signal at H level output from the output-side circuit part 24c1 is quickened as compared with the case the output signal at L level is output.

As described above, according to the fifth embodiment, the signal output from the output-side circuit part 24c1 (shift register circuit) when the transistor PT21 is in on state can be delayed by connecting the high resistance R 21 between the transistor PT25 and the clock signal line (CLK). Thus, according to the fifth embodiment, because of the high resistance R21 having the same resistance value about 100 kΩ as in the first embodiment, the shift amount of timing between the output signal when the transistor PT21 is in on state and the output signal when the PT21 is in off state is more than about 20 nsec. Therefore, like in the first embodiment, since a predetermined stage of horizontal switch can be turned on after the horizontal switch two stages prior to the predetermined stage was turned off, a noise is prevented from being generated in an picture signal because the predetermined stage of horizontal switch is turned on, at the moment the horizontal signal two stages prior to the predetermined stage is switched from on state to off state. As a result, there can be provided a liquid crystal display which can prevent the image deterioration caused by the noise of the picture signal while prevent an increase in power consumption.

### Sixth Embodiment

According to a sixth embodiment, a description is made of a case an n-channel transistor is used instead of the p-channel in the fifth embodiment.

That is, as shown in FIG. 12, an output-side circuit part 34c1 of a shift register circuit constituting a H driver of a liquid crystal display according to the sixth embodiment comprises transistors NT21, NT22, NT23 and NT24, a diode-connected transistor NT25 and a capacitor C21 formed by connecting the source and the drain of the transistor. In addition, the output-side circuit part 34c1 is an example of a “first circuit part” in the present invention. In addition, the transistors NT21, NT22, NT23 and NT24 are examples of a “first transistor”, a “second transistor”, a “third transistor” and a “fourth transistor” in the present invention.

Here, according to the sixth embodiment, the output-side circuit part 34c1 further comprises a high resistance R21 having a resistance value of about 100 kΩ.

According to the sixth embodiment, the p-channel transistors NT21 to NT25, and the p-channel transistor constituting the capacitor C21 are all constituted by TFT's (thin film transistor) consisting of p-type MOS transistors (field effect transistors).

In addition, according to the sixth embodiment, the transistor NT23 is formed so as to have two gate electrodes electrically connected to each other like the second embodiment shown in FIG. 7.

As shown in FIG. 12, the transistors NT21 to NT25, the capacitor C21 and the high resistance R21 of the sixth embodiment are connected to the positions corresponding to the transistors PT21 to PT25, the capacitor C21 and the high resistance R21 of the fifth embodiment shown in FIG. 11. In other words, according to the sixth embodiment, the high resistance R21 is connected between the transistor NT25 and the clock signal line (CLK). However, sources of the transistors NT22 and NT23 are connected to a negative-side potential VSS and a drain of the transistor NT21 is connected to a positive-side potential VDD.

The constitution of the sixth embodiment other than the above is the same as in the fifth embodiment.

According to the sixth embodiment, as described above, like in the fifth embodiment, there can be provided a liquid crystal display which can prevent an image deterioration caused by the noise of the picture signal while prevent an increase in power consumption, by connecting the high resistance R21 between the transistor NT25 and the clock signal line (CLK).

In addition, the illustrated embodiments are thought to be illustrative and not restrictive in all respects. The scope of the present invention is not shown by the above description the embodiments but shown by terms of the appended claims, and various kinds of variation is included in the same meaning and scope as in the claims.

For example, another value of the high resistance may be set instead of the value shown in the embodiments 1 to 6. In this case, a shift amount of timing between the predetermined stage of output signal and the output signal two stages prior to the predetermined stage can be controlled by adjusting the value of the high resistance.

Furthermore, the present invention can be applied to a display other than the liquid crystal display and the organic EL display in the embodiments 1 to 6.

In addition, the on-resistance of the fourth transistor may not be lower than the on-resistance of the third resistance as in the embodiments 1 to 4.

What is claimed is:

1. A display provided with a shift register circuit including a first circuit part comprising:
a first transistor of first conductivity type connected to a first potential side and turned on in response to a clock signal;
a second transistor of first conductivity type connected to a second potential side;
a third transistor of first conductivity type connected between a gate of said first transistor and said second potential; and
a high resistance connected between the gate of said first transistor and a clock signal line supplying said clock signal.

2. The display according to claim 1, wherein
said high resistance has a resistance value set such that the moment said first transistor of a predetermined stage of shift register circuit is switched from off state to on state may not overlap with the moment said first transistor of the shift register circuit two stages prior to the predetermined stage is switched from on state to off state.

3. The display according to claim 2, wherein
said high resistance has a value set such that said first transistor of the predetermined stage of shift register circuit is turned on, after said first transistor of the shift register circuit two stages prior to the predetermined stage was turned off.

4. The display according to claim 3, wherein a signal corresponding to said first potential is output from said first circuit part through said first transistor, and
an output signal of said first circuit part of the predetermined stage of shift register circuit is switched from said second potential to said first potential, after an output signal of said first circuit part of the shift register circuit two stages prior to the predetermined stage was switched from said first potential to said second potential.

5. The display according to claim 1, wherein
said first circuit part further comprises a diode-connected fourth transistor connected between the gate of said first transistor and said clock signal line and having an on-resistance lower than that of said third transistor.

6. The display according to claim 5, wherein
said fourth transistor is a p-type field effect transistor.

7. The display according to claim 5, wherein
said fourth transistor has two gate electrodes electrically connected to each other.

8. The display according to claim 1, wherein
said first circuit part further comprises a fourth transistor connected between the gate of said first transistor and said clock signal line and turned on in response to a signal by which a period of on state which does not overlap with a period of on state of said third transistor is provided.

9. The display according to claim 8, wherein said fourth transistor is a p-type field effect transistor.

10. The display according to claim 8, further comprising a diode-connected fifth transistor connected between said fourth transistor and said clock signal line.

11. The display according to claim 10, wherein said fifth transistor is a p-type field effect transistor.

12. The display according to claim 1, wherein
a capacitor is connected between the gate and the source of said first transistor.

13. The display according to claim 1, wherein
said third transistor has a function of turning said first transistor off when said second transistor is in on state.

14. The display according to claim 1, wherein
at least said first transistor, said second transistor and said third transistor are p-type field effect transistors.

15. The display according to claim 1, wherein
at least said third transistor has two gate electrodes electrically connected to each other.

16. The display according to claim 1, wherein
said first circuit part is arranged on an output side of said shift register circuit, and
a second circuit part comprising said first transistor, said second transistor and said third transistor but not comprising said high resistance is arranged on an input side of said shift register circuit.

17. The display according to claim 1, wherein
said shift register circuit comprises a shift register circuit for driving a drain line to which a picture signal is supplied.

18. The display according to claim 17, wherein
said drain line driven by said shift register circuit has a function of supplying said picture signal to a display pixel comprising a liquid crystal.

19. The display according to claim 17, wherein
said drain line driven by said shift register circuit has a function of supplying said picture signal to display pixel comprising an organic EL element.
